(19) United States
(12) Patent Application Publication
(10) Pub. No.: US 2026/0333674 A1
(43) Pub. Date: Oct. 22, 2026

(54) DRAM DEVICE HAVING 3.5F2 STRUCTURE LAYOUT

(71) Applicant: TAESUNG ENVIRONMENTAL RESEARCH INSTITUTE CO., LTD., Ulsan (KR)

(72) Inventors: Gi Yeol YUN, Ulsan (KR); Seok Man KIM, Ulsan (KR); Chai Rok LIM, Ulsan (KR); Hyeok-Je JEONG, Gimhae-si (KR); Myung-Kon JO, Ulsan (KR)

(73) Assignee: TAESUNG ENVIRONMENTAL RESEARCH INSTITUTE CO., LTD., Ulsan (KR)

(21) Appl. No.: 19/401,976

(22) Filed: Nov. 26, 2025

(30) Foreign Application Priority Data
Apr. 17, 2025 (KR) 10-2025-0050484

(51) Int. Cl. H10B 12/00

(52) U.S. Cl. CPC H10B 12/482; H10B 12/488

(57) ABSTRACT

A DRAM device having a 3.5F2 structure layout including: a substrate; a plurality of bit lines disposed on the substrate; a plurality of channel patterns arranged in a honeycomb structure on the bit lines; a plurality of word lines contacting the body region; and a gate insulating pattern disposed between the plurality of channel patterns and the plurality of word lines, wherein the plurality of word lines include first and second word lines disposed at different heights from each other, and the first and second word lines are alternately arranged with each other in the first horizontal direction; wherein the bit line is formed in a corrugated structure over its entire length such that the entire area of each channel pattern is positioned on the bit line, and wherein a plurality of the channel patterns electrically connected to a single word line are arranged in a straight line.

### CROSS-REFERENCE TO RELATED APPLICATION

This application claims priority to and the benefit of Korean Patent Application No. 10-2025-0050484, filed on April 17, 2025, the disclosure of which is incorporated herein by reference in its entirety.

### BACKGROUND

### 1. Field of the Invention

The present invention relates to a DRAM device, and more particularly, to a DRAM device having a layout of a 3.5F2 structure (an example of sub-4F2 structure).

### 2. Discussion of Related Art

A DRAM cell has a 1T1C (one transistor-one capacitor) structure that stores and reads data, and is composed of a capacitor and a transistor (Non-Patent Document 1).

In a DRAM cell, the capacitor stores charge to preserve logical information, and the transistor is controlled to turn on/off by a word line to provide a data path between the capacitor and a bit line. The bit line is a data transmission path, and the word line serves as a signal line that activates or deactivates the transistor as the gate of the transistor. In this configuration, the operation of the DRAM cell is divided into writing, reading, and refreshing, and weak signal amplification and periodic data recharging are performed through a Sense Amplifier and Refresh Circuitry, among others.

Meanwhile, the main operating processes of a DRAM cell can be divided into a Write Operation, a Read Operation, and a Refresh Operation. The write operation is an operation for storing data, where the word line is activated to turn on the access transistor, input data is transmitted to the capacitor through the bit line (positive charge is stored in the capacitor for logic '1', and negative charge is stored in the capacitor for logic '0'), the word line is deactivated to turn off the access transistor, and the data is stored in the capacitor. The read operation is an operation for reading data, where the word line is activated to turn on the access transistor, the charge state of the capacitor is transmitted to the bit line (if there is positive charge in the capacitor, a slight voltage rise is detected in the bit line, and if there is negative charge in the capacitor, a slight voltage drop is detected in the bit line), and the data on the bit line is amplified by a Sense Amplifier and converted into a readable signal.

Since the capacitor of a DRAM undergoes natural discharge over time, it needs to be periodically refreshed to avoid losing data, which is called the refresh operation. The refresh cycle is generally in units of several milliseconds (ms), and it replenishes the charge by reading the cell data and then writing the same data back.

Key characteristics of a DRAM cell include: it is a volatile memory where data is lost as the capacitor's charge discharges when power is cut off; its simple 1T1C structure allows for high integration density, fast access, and operation with low power; and it requires a periodic refresh cycle to maintain data, which consumes additional power.

Major considerations during DRAM cell operation include: as DRAM cells are miniaturized, the capacitor capacitance decreases, making it difficult to store sufficient charge, which can reduce data stability; interference (coupling noise) may occur between adjacent bit lines; and a sufficient margin (sensing margin) is needed to distinguish signals from noise during a read operation. Through these operations, the DRAM cell stores, reads, and maintains data, performing its role as a high-density and high-performance memory.

As the integration density of semiconductor memory devices has increased, the cell structure has been continuously scaled down from 8F² and 6F² to 4F² to reduce the area occupied by each unit memory cell in a planar manner. Correspondingly, various technologies have been proposed to implement components such as transistors, bit lines, word lines, and capacitors within the 4F² cell structure.

In particular, as one method for reducing the unit cell area, DRAM devices including vertical channel transistors, which induce a vertical channel by arranging source and drain regions vertically, have been studied. Chung et al. proposed a new 4F² DRAM cell structure applying a vertical pillar transistor (VPT) (Non-Patent Document 2). It was expected that using such vertical channel transistors could enhance cell area efficiency.

However, in the vertical channel transistor of Non-Patent Document 2, the channel pillar and the cell capacitor are in direct contact, causing leakage current to flow during data storage. As a result, the retention time is shortened, requiring frequent refreshes and increasing power consumption.

Meanwhile, in the semiconductor device field, there is a continuous pursuit of reducing the minimum feature size (F) and achieving smaller cell layouts to increase capacity per unit area. However, the minimum spacing for wirings formed on the same plane, such as word lines, has faced physical limitations in the manufacturing process. This makes it difficult to further increase the capacity per unit area with the device of Non-Patent Document 2 alone.

Furthermore, the alignment tolerance margin between the channel pattern and the bit line is very limited, leading to poor pattern alignment in the manufacturing process and concerns about yield degradation. (Non-Patent Literature 1) Robert H. Dennard, “Operation of a One-Transistor Cell Used in a High-Density DRAM", IEEE Journal of Solid-State Circuits, Vol. SC-9, No. 5, Oct. 1974

(Non-Patent Literature 2) Chung et al., “4F2 DRAM Cell with Vertical Pillar Transistor (VPT)”, 2011 Proceedings of the European Solid-State Device Research Conference (ESSDERC), 2011

### SUMMARY OF THE INVENTION

One of the various objects of the present invention is to provide a DRAM device that can enhance operational reliability and manufacturing process yield by improving the electrical contact alignment between the channel of a vertical channel transistor and the bit line.

Another object of the present invention is to provide a DRAM device that can secure process margin for pattern alignment errors while minimizing unit cell area by optimizing the arrangement of word lines and bit lines.

According to one aspect, a DRAM device having a 3.5F2 structure layout is disclosed, the device comprising: a substrate; a plurality of bit lines disposed on the substrate, oriented in a first horizontal direction, and arranged parallel to each other at a predetermined interval; a plurality of channel patterns arranged in a honeycomb structure on the bit lines and each extending in a vertical direction, wherein each channel pattern includes an upper electrode and a lower electrode, and a region between the upper electrode and the lower electrode is a body region; a plurality of word lines contacting the body region, oriented in a second horizontal direction perpendicular to the first horizontal direction, and arranged parallel to each other at a predetermined interval; and a gate insulating pattern disposed between the plurality of channel patterns and the plurality of word lines, wherein the plurality of word lines include first and second word lines disposed at different heights from each other, and the first and second word lines are alternately arranged with each other in the first horizontal direction; wherein the bit line is formed in a corrugated structure over its entire length such that the entire area of each channel pattern is positioned on the bit line, and a plurality of the channel patterns electrically connected to a single word line are arranged in a straight line.

In one embodiment, each of the plurality of channel patterns may include an upper electrode and a lower electrode, and the lower electrode may contact the bit line.

In one embodiment, the bit line may be formed in a sinusoidal curve shape.

In one embodiment, the bit line may be formed in an angular zigzag shape.

In one embodiment, the device may further comprise a gate conductive pattern disposed between the word line and the gate insulating pattern.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a perspective view of a vertical channel transistor according to an embodiment of the present invention.

FIG. 2 is a cross-sectional view taken along line A-A' of FIG. 1.

FIG. 3 is a cross-sectional view taken along line B-B' of FIG. 1.

FIG. 4 is a schematic plan view of the vertical channel transistor of FIG. 1.

FIG. 5 is a perspective view of a DRAM device including the vertical channel transistor of FIG. 1.

FIG. 6A is a plan view of a DRAM device including a conventional 4F2 structure vertical channel transistor, and FIG. 6B is a plan view of a DRAM device including a vertical channel transistor in which the spacing between adjacent word lines or bit lines is reduced by half.

### DETAILED DESCRIPTION OF EXEMPLARY EMBODIMENTS

Hereinafter, exemplary embodiments will be described in detail with reference to the accompanying drawings. However, the descriptions herein may be embodied in many different forms and should not be construed as limited to the embodiments set forth herein.

Throughout the specification, when a part is "connected" to another part, this includes not only "directly connected" cases but also "indirectly connected" cases with other members interposed between them. Also, when a member is described as being "on", "above", "on top of", "under", "below", or "at the bottom of" another member, this includes not only cases where the member is in contact with the other member but also cases where another member exists between the two members.

Throughout this specification, when a part “comprises” or "includes" a certain component, it means that it can further include other components, not excluding other components, unless otherwise specified.

The embodiments described in this specification will be explained with reference to perspective views, cross-sectional views, etc., which are ideal exemplary diagrams of the present invention. Also, throughout the specification, the same reference numerals denote the same constituent elements. At this time, detailed descriptions of known functions and configurations that could obscure the gist of the present invention have been omitted.

And, in each drawing illustrated in the present invention, each constituent element may be somewhat exaggerated or reduced for convenience of explanation. Furthermore, the embodiments of the present invention are not limited to the specific forms shown, but also include changes in form that may be generated according to the manufacturing process.

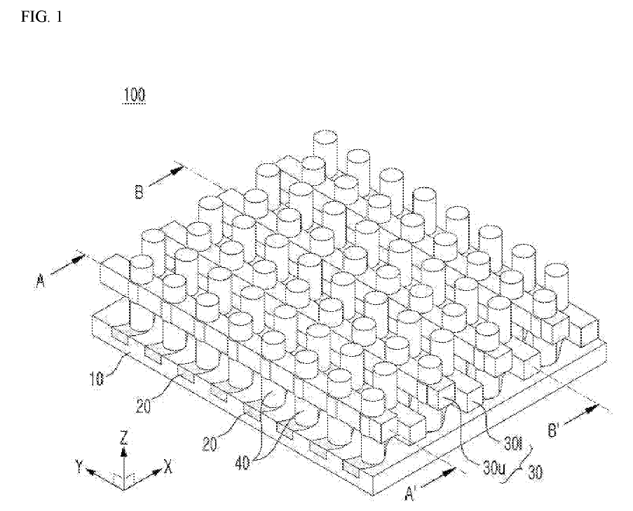

FIG. 1 is a perspective view schematically illustrating a vertical channel transistor according to an embodiment of the present invention. Referring to FIG. 1, the vertical channel transistor (100) according to an embodiment of the present invention includes: a substrate (10); a plurality of bit lines (20) formed on the substrate (10) and extending parallel to each other at a predetermined interval in a first horizontal direction (e.g., x-axis direction); a plurality of word lines (30u, 30l) disposed on the bit lines (20) and extending parallel to each other at a predetermined interval in a second horizontal direction (e.g., y-axis direction) substantially perpendicular to the first horizontal direction; a plurality of channel patterns (40) disposed on the bit lines (20) in a matrix form, for example, a honeycomb structure, and each protruding in a vertical direction (e.g., z-axis direction); and a gate insulating pattern (not shown) interposed between the channel patterns (40) and the word lines (30u, 30l).

Here, the channel pattern (40) is a semiconductor region in the form of an elongated pillar and functions as the channel of the transistor, each including an upper electrode (40u) and a lower electrode (40l). The region between the upper electrode (40u) and the lower electrode (40l) corresponds to the body region of the transistor.

The substrate (10) may include, for example, a Group IV semiconductor material such as silicon (Si), germanium (Ge), silicon germanium (SiGe), or silicon carbide (SiC), a Group III-V semiconductor material such as gallium arsenide (GaAs), indium arsenide (InAs), or indium phosphide (InP), an oxide semiconductor, a nitride semiconductor, or an oxynitride semiconductor. Specifically, the substrate may be a silicon substrate doped with p-type impurities, but is not limited thereto.

The bit line (20) is a wiring that connects the lower electrodes (40l) of each memory cell in the vertical channel transistor, extending along the first horizontal direction (e.g., x-axis direction). The bit line (20) is buried within the substrate and is formed in a corrugated structure over its entire length such that the entire area of the channel pattern (40) is positioned on the bit line (20). As a result, the contact alignment between the channel pattern (40) and the bit line (20) is significantly improved, and the overlap area between the channel pattern (40) and the bit line (20) is maximized, enhancing electrical connection reliability.

Furthermore, since the lower electrode (40l) of the channel pattern (40) contacts the bit line (20) over its entire surface, even if the channel pattern (40) and the bit line (20) are misaligned due to mask alignment errors, a contact area equal to or greater than a certain area is secured, thereby increasing the process error tolerance. Moreover, since most of the bit line (20) is covered by the channel pattern (40), unnecessary capacitance between the bit line (20) and the substrate (10) is reduced, and interference between adjacent bit lines can also be mitigated.

The plurality of word lines (30) include first and second word lines (30u and 30l) disposed at different heights from each other, and the first and second word lines (30u and 30l) are alternately arranged with each other in the first horizontal direction (e.g., x-axis direction). A plurality of channel patterns contacting a single word line are arranged in a straight line.

The vertical channel transistor (100) corresponds to the transistor part of a DRAM cell, which consists of one transistor and one capacitor. A DRAM device (200) is implemented by arranging a plurality of vertical channel transistors (100) in a matrix form. The bit lines (20) and the word lines (30u, 30l) are arranged in directions orthogonal to each other, forming a cross-point array. Accordingly, one channel pattern (40) is disposed at each intersection where the plurality of bit lines (20) and the plurality of word lines (30u, 30l) cross. That is, a vertical channel transistor (100) is formed at each matrix intersection of the bit lines (20) × word lines (30).

Although a single transistor (100) is shown in the drawing, in practice, such transistors (100) are repeatedly arranged in row and column directions to constitute the memory cell array of the DRAM device (200).

Electrodes (not shown) are formed on the top and bottom of the plurality of channel patterns (40), respectively. The region between the upper electrode (40u) and the lower electrode (40l) is a body region (not shown), which has the same polarity as the substrate (10), while the upper electrode (40u) and the lower electrode (40l) have a different polarity from the substrate (10). For example, if the substrate (10) is a p-type semiconductor substrate, the body region has p-type polarity, and the upper electrode (40u) and the lower electrode (40l) have n-type polarity. In this case, the upper electrode (40u) and the lower electrode (40l) can be formed by implanting n-type impurity ions into the top and bottom of the channel pattern (40), respectively, and performing drive-in diffusion.

If necessary, the names or roles of the upper electrode (40u) and the lower electrode (40l) may be interchanged. For example, in the DRAM cell, the upper electrode (40u) may serve as the drain (connection to the capacitor side) and the lower electrode (40l) may serve as the source (connection to the bit line side), or vice versa.

The lower electrode (40l) is in direct contact with and electrically connected to the adjacent bit line (20). That is, the lower electrode (40l) acts as a data input/output node via the bit line (20), through which current is injected or extracted during write/read operations of the channel pattern (40).

Meanwhile, the upper electrode (40u) is a region connected to a capacitor to be described later and corresponds to the storage node of the memory cell. The upper electrode (40u) of each channel pattern (40) is connected to one terminal of an individual cell capacitor, and the other terminal of the capacitor is connected to a common electrode (e.g., ground or plate voltage) to complete the one transistor-one capacitor (1T1C) cell configuration. Although the specific structure of the capacitor is not shown in FIG. 1, the cell capacitor may be any capacitor structure comprising a storage electrode electrically connected to the upper electrode (40u), a dielectric layer surrounding it, and a ground electrode.

A gate (50) is formed to surround the side of the channel pattern (40) between the upper electrode and the lower electrode. The gate (50) corresponds to the gate electrode of the vertical channel transistor (100) and surrounds the body region of the channel pattern (40). The gate (50) may be composed of a gate insulating pattern (52) and a gate conductive pattern (54).

The gate insulating pattern (52) is an insulating film formed to surround the periphery of the channel pattern (40) and may be made of a dielectric material such as silicon oxide (SiO₂) or silicon nitride (Si₃N₄). The gate conductive pattern (54) is a conductive layer formed on the outer side of the gate insulating pattern (52) and may be formed of a conductive material such as polycrystalline silicon (polysilicon), metal, or metal silicide.

The gate (50) extends in the vertical direction, wrapping around the body region of the channel pattern (40) in a cylindrical shape, and its height is preferably set to cover the heights of both the lower second word line (30l) and the upper first word line (30u). This is to ensure that the gate (50) extends over the entire height of the channel pattern, allowing the word lines (30u, 30l) formed in two layers, top and bottom, to connect to the same gate (50) at different heights.

For example, the gate (50) may be formed as a continuous (integral) structure surrounding the entire channel pattern. In this case, one gate electrode is provided for each channel pattern, and the lower side surface of the gate electrode is surrounded and contacted by the second word line (30l), while the upper side surface is surrounded and contacted by the first word line (30u).

As another example, for implementation in the manufacturing process, the gate conductive pattern (54) may be vertically divided into two parts and formed, corresponding to the heights of the first word line and the second word line, respectively. In the latter case, two gate electrodes connected in series are formed at the top and bottom for one channel pattern (40), and either the continuous gate method or the split gate method can be appropriately selected and applied depending on the driving method or process choice.

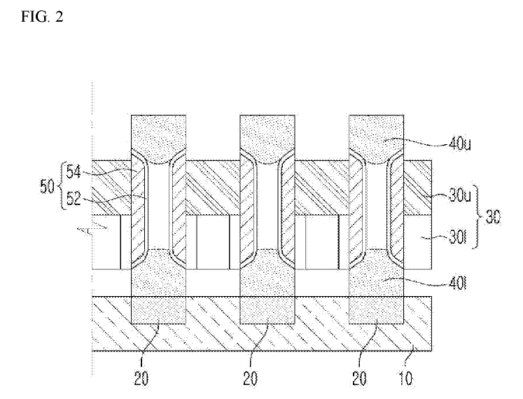

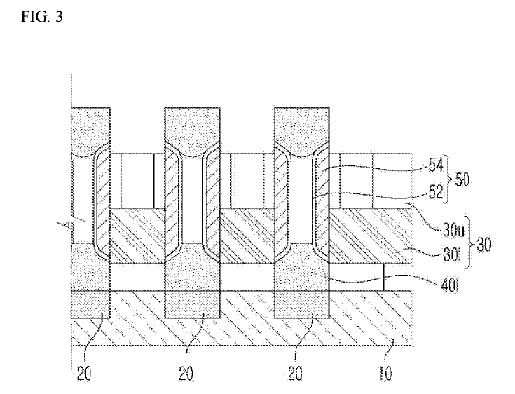

FIG. 2 is a cross-sectional view taken along line A-A' of FIG. 1, and FIG. 3 is a cross-sectional view taken along line B-B' of FIG. 1.

Referring to FIGS. 2 and 3, the plurality of word lines (30u and 30l) include the first word line (30u) and the second word line (30l) disposed at different heights from each other, and the first and second word lines are alternately arranged with each other in the first horizontal direction (e.g., x-axis direction).

The first and second word lines (30u and 30l) are formed to surround the gate (50) of the channel pattern (40) at different heights. More specifically, the second word line (30l) surrounds the side surface of the gate (50) of the channel pattern (40) at a relatively lower height, and the first word line (30u) is formed to surround the side surface of the gate (50) of the channel pattern at a height above that. In other words, in the portion of the word line surrounding the gate (50) of each channel pattern (40), the second word line (30l) is located on the lower side, and the first word line (30u) is located slightly on the upper side, each electrically connected to the gate (50) of the channel pattern.

In conventional vertical channel transistors, the plurality of word lines are arranged side-by-side at substantially the same height, posing a physical limitation in increasing the capacity per unit area. However, in the present invention, adjacent word lines are disposed at different heights, which allows the spacing between word lines to be significantly reduced compared to when word lines are formed side-by-side on the same plane. That is, the minimum feature size (F) can be easily reduced, and as a result, capacity per unit area can be increased, integration density can be improved, and electrical interference between adjacent word lines is also mitigated.

The first word line (30u) and the second word line (30l) are electrically independent, individual lines. Each word line (30u, 30l) can be formed of a conductive material such as metal, semiconductor, or alloy, for example, a metal such as polysilicon, tungsten, copper, aluminum, molybdenum, or titanium, or a silicide, or an alloy thereof. However, since the two word line layers are formed in different process steps, they do not necessarily need to be formed of the same material.

If necessary, the first word line (30u) and the second word line (30l) may be formed of the same material, or they may be formed of different materials. For example, a modification is possible where the lower layer, the second word line (30l), is formed of polysilicon, and the upper layer, the first word line (30u), is formed of metal.

Spacers (not shown) may be provided on the sidewalls of the first and second word lines (30u and 30l), which serve to block each word line from unnecessarily contacting or interfering with the gate of another channel pattern not assigned to it. For example, the first word line (30u) of the upper layer can be isolated from the lower end of the gate (50) of an adjacent channel pattern (40) by an insulating spacer interposed below it, and the second word line (30l) of the lower layer can be prevented from contacting the upper end of the gate of an adjacent channel by an insulating spacer above it. Through this structure, the multi-layer word lines (30u, 30l) selectively control only the intended channel patterns and avoid electrical interference while being arranged crossing each other. The spacers can serve to prevent contact with other channel patterns (40) that are not interconnected by the first and second word lines (30u and 30l).

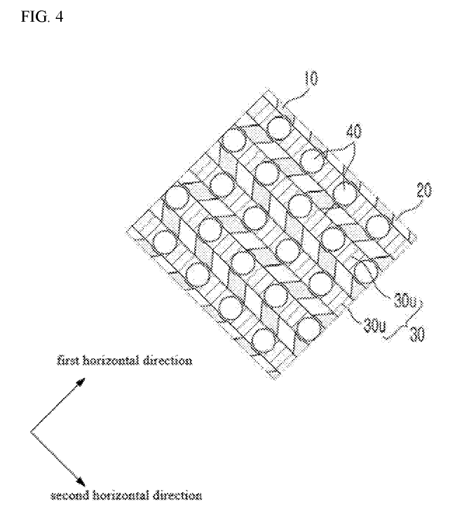

FIG. 4 is a schematic plan view of the vertical channel transistor of FIG. 1. FIG. 4 omits the illustration of capacitors and wirings connected to the top of the channel patterns (40), focusing on the arrangement structure of the channel patterns (40).

Referring to FIG. 4, the plurality of channel patterns (40) are arranged in a honeycomb structure on the bit line (20). Here, the honeycomb structure refers to a structure where channel patterns are placed at the center point and the six vertices of a hexagon, such that each channel pattern located at the six vertices becomes the center point of each of the 6 neighboring hexagons. In the honeycomb structure, the hexagon may be a regular hexagon, and the 6 triangles sharing the center point may all be equilateral triangles.

Referring to FIG. 4, the plurality of bit lines (20) extending in the first horizontal direction (x-axis direction) are arranged in a wavy form. Each bit line (20) curves left and right along its path, sequentially connecting the plurality of channel patterns (40). As shown, the channel patterns (40) are arranged at regular intervals, but the channel patterns in adjacent rows are slightly offset laterally, forming a staggered, i.e., honeycomb, grid arrangement. Accordingly, one bit line (20) follows a zigzag path, enabling it to contact all the alternately positioned channel patterns.

On the other hand, the plurality of word lines (30u, 30l) each extend in a straight line in the second horizontal direction (y-axis direction) and are respectively connected to the gates (50) of the alternately arranged channel patterns. For example, as seen in FIG. 4, the first word line (30u) is connected only to the gates of channel patterns arranged in one line, and the gates of the channel patterns arranged alternately in between are connected to the second word line (30l) on the layer below.

This planar arrangement allows the spacing between adjacent channel patterns to be efficiently reduced, enabling the unit area of the cell to be formed smaller than in conventional ones. That is, by arranging the plurality of channel patterns (40) in a honeycomb structure, a 3.5F2 structure can be achieved without adjusting the width of the bit line (20), the width of the word line (30), and the spacing between adjacent bit lines (20). For example, when the diameter of each channel pattern (40), the width of the bit line (20), the width of the word lines (30u and 30l), and the spacing between adjacent bit lines (20) are all equal to F, the area of the parallelogram connecting four channel patterns is about 3.464F² (=2F×2Fsin60°).

Consequently, there is an advantage in that the 3.5F2 structure can be easily achieved without increasing the bit line capacitance, bit line-word line capacitance, and bit line-substrate capacitance, that is, while maintaining the ratio of bit line capacitance (Cb) to cell capacitance (Cs) at the same level as conventional ones.

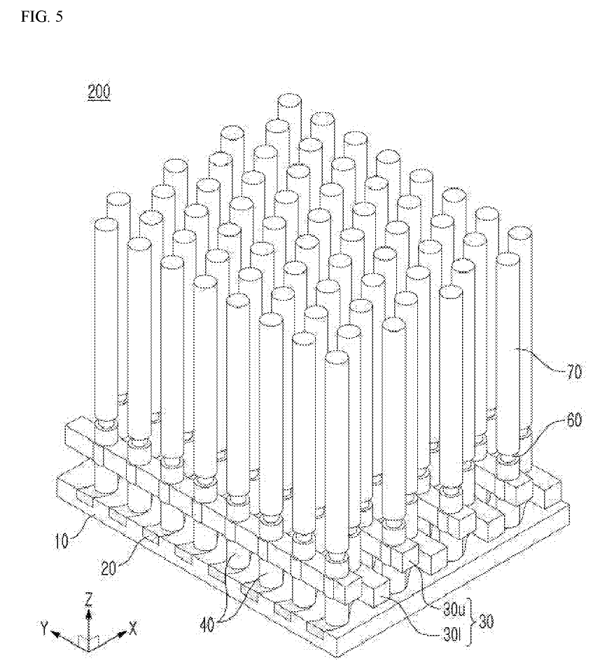

FIG. 5 is a perspective view schematically illustrating a DRAM device including the vertical channel transistor of FIG. 1. Referring to FIG. 5, a capacitor (70) is connected to the upper part of each vertical channel transistor (100). The capacitor (70) is a device for securing the data storage capacity of the memory cell and is electrically connected to the upper electrode (40u) of the channel pattern (40).

The capacitor (70) may be, for example, a stacked capacitor composed of a cylinder-shaped lower electrode, a dielectric layer, and an upper electrode. Although not shown, the upper electrodes of the plurality of memory cell capacitors may be connected to a common potential (node). The lower electrode of the capacitor (70) is connected to the upper electrode (40u) of the channel pattern (40) to form a storage node, and the upper electrode of the capacitor (70) operates as a common plate electrode. Meanwhile, the lower electrode (40l) of the channel pattern (40) is connected to the bit line (20) as described above.

In this way, the vertical channel transistor (100) and the capacitor (70) are combined to form one memory cell, and these memory cells are arranged in an X-Y matrix form to constitute the DRAM device (200). The DRAM device (200) is addressed by the plurality of bit lines (20) and the plurality of word lines (30u, 30l). By turning on the transistor of the selected cell, data stored in the capacitor (70) can be read out to the bit line (20) (Bitline Sensing), or conversely, data can be stored in the capacitor via the bit line.

A contact plug (60) may be further interposed between the capacitor (70) and the channel pattern (40). Through this, the DRAM device (200) utilizing the vertical channel transistor (100) as a memory cell is constructed. Such a vertical channel transistor (100) is versatile enough to be applicable not only to the memory devices described above but also to transistors in non-memory devices such as a central processing unit (CPU).

Hereinafter, the technical reason why the minimum feature size F can be easily reduced because adjacent word lines are disposed at different heights from the bit line will be described in more detail.

In the field of DRAM devices, the minimum feature size F is an important factor that determines the integration density and performance of the device. The minimum feature size F means the smallest line width that can be drawn in a semiconductor circuit, and is generally the smallest of (1) the width of the word line, (2) the width of the bit line, (3) the spacing between adjacent word lines, and (4) the spacing between adjacent bit lines. The smaller the minimum feature size F, the higher the transistor density of the semiconductor chip, the smaller the chip size, and the lower the power consumption. Therefore, technological development in the DRAM device field is moving in the direction of adopting the smallest possible minimum feature size F.

However, this minimum feature size cannot be reduced indefinitely and is usually determined by the level of technological development at the time of manufacturing. Specifically, it is determined by the resolution of photolithography equipment and the quality and performance of the photoresist.

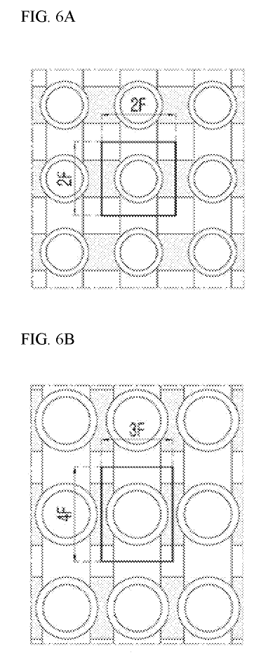

FIG. 6A is a plan view of a DRAM device including a conventional 4F2 structure vertical channel transistor. In FIG. 6A, (1) the width of the word line, (2) the width of the bit line, (3) the spacing between adjacent word lines, and (4) the spacing between adjacent bit lines are all set to F, thus having a 4F2 structure.

FIG. 6B is a plan view of a DRAM device including a vertical channel transistor, manufactured by reducing (3) the spacing between adjacent word lines to half (1/2) compared to (1) the width of the word line, (2) the width of the bit line, and (4) the spacing between adjacent bit lines. In this case, (3) the spacing between adjacent word lines becomes the minimum feature size F. Since this minimum feature size F is determined by the level of technological development at the time of manufacturing, it ultimately results in an increase in the unit cell area (12F2 = 4F × 3F). That is, adjusting the spacing between adjacent word lines to reduce the unit cell area is by no means desirable.

However, in the present invention, as long as the spacing between adjacent first word lines and the spacing between adjacent second word lines are each equal to or greater than the minimum feature size F, the horizontal spacing between an adjacent first word line and second word line can be adjusted arbitrarily. This is because word lines formed on different planes (different heights) are formed in different process steps, so they are not affected by the minimum feature size determined by the level of technology at the time of manufacturing. Theoretically, the horizontal spacing between an adjacent first word line and second word line can be adjusted down to 1/2F.

Therefore, the DRAM device according to an aspect of the present invention has the advantage of achieving an improved capacity per unit area compared to the capacity per unit area generally achievable at the level of technological advancement at the time of manufacturing.

The DRAM device according to an aspect of the present invention has an effect of improving the electrical contact alignment between the channel pattern and the bit line and increasing the alignment error tolerance margin between the channel and the bit line, by forming the bit line in a corrugated structure instead of the conventional linear structure. In addition, the DRAM device according to an aspect of the present invention can reduce interference and unnecessary parasitic capacitance between the channel pattern and the substrate, thereby reducing signal interference and improving the sensing margin. Furthermore, the DRAM device according to an aspect of the present invention forms the word lines in multiple layers to reduce the spacing between adjacent word lines and, at the same time, optimizes the cell layout by changing the shape of the bit line, thereby improving process alignment for high-integration cell implementation and enhancing manufacturing yield. Due to these technical effects, the DRAM device of the present invention can increase the capacity per cell area compared to conventional devices and can enhance the overall reliability of the memory device. The effects of one aspect of the present invention are not limited to the effects described above, and should be understood to include all effects that can be inferred from the configurations described in the detailed description or claims of this specification.

The foregoing description in this specification is for illustrative purposes, and those of ordinary skill in the art to which this aspect of the specification pertains will be able to understand that easy modifications into other specific forms are possible without changing the technical spirit or essential features described in this specification.

For example, in this embodiment, the bit line (20) is illustrated as proceeding in a wavy shape with a constant width, but as another embodiment, instead of implementing the bit line in a curved shape, it may be formed as a polygonal zigzag line. That is, the bit line (20) may be formed corrugated in a curved shape (e.g., a sinusoidal shape), or it may be formed corrugated in a zigzag shape made of angular line segments. The exact shape of the corrugated structure may vary depending on the design and process, and all such modifications are included in the scope of the present invention.

Furthermore, a modification is also possible where a part of the channel pattern (40) is connected to a region of the semiconductor substrate (10) to substantially ground the channel body to the substrate. For example, the base portion or a part of the outer periphery of the channel pattern (40) may be formed to be continuous with the p-type region of the substrate (10). Adopting such a structure allows the bias voltage applied to the substrate (10) to be transmitted to the body region of the channel pattern, creating a kind of back-bias effect. As a result, the transistor's body is not floating and is maintained at a stable potential. This helps to reduce the unwanted floating body effect and decrease transistor threshold voltage variations or the occurrence of leakage paths.

Therefore, the embodiments described above should be understood as exemplary in all respects and not restrictive. For example, each component described as a single unit may be implemented in a distributed manner, and likewise, components described as distributed may be implemented in a combined form.

The scope of this specification is indicated by the claims described below, and all changes or modified forms derived from the meaning and scope of the claims and their equivalent concepts should be interpreted as being included in the scope of this specification.

What is claimed is:

1. A DRAM device having a 3.5F2 structure layout, the DRAM device comprising:
a substrate;
a plurality of bit lines disposed on the substrate, oriented in a first horizontal direction, and arranged parallel to each other at a predetermined interval;
a plurality of channel patterns arranged in a honeycomb structure on the bit lines and each extending in a vertical direction, wherein each channel pattern includes an upper electrode and a lower electrode, and a region between the upper electrode and the lower electrode is a body region;
a plurality of word lines contacting the body region, oriented in a second horizontal direction perpendicular to the first horizontal direction, and arranged parallel to each other at a predetermined interval; and
a gate insulating pattern disposed between the plurality of channel patterns and the plurality of word lines,
wherein the plurality of word lines include first and second word lines disposed at different heights from each other, and the first and second word lines are alternately arranged with each other in the first horizontal direction,
wherein the bit line is formed in a corrugated structure over its entire length such that the entire area of each channel pattern is positioned on the bit line, and
wherein a plurality of the channel patterns electrically connected to a single word line are arranged in a straight line.

2. The DRAM device of claim 1, wherein each of the plurality of channel patterns includes an upper electrode and a lower electrode, and the lower electrode contacts the bit line.

3. The DRAM device of claim 1, wherein the bit line is formed in a sinusoidal curve shape.

4. The DRAM device of claim 1, wherein the bit line is formed in an angular zigzag shape.

5. The DRAM device of claim 1, further comprising a gate conductive pattern disposed between the word line and the gate insulating pattern.
